(19) United States
(12) Patent Application Publication
(10) Pub. No.: US 2026/0362993 A1
(43) Pub. Date: Nov. 12, 2026

(54) COATING COMPOSITION FOR COVERING A SURFACE AREA COMPRISING TUNGSTEN ON A SEMICONDUCTOR DEVICE DURING AN ATOMIC LAYER DEPOSITION PROCESS

(71) Applicant: BASF SE, Ludwigshafen am Rhein (DE)

(72) Inventors: Che Wei WANG, Taoyuan City (TW); Chia Chien YEH, Taoyuan City (TW); Jhih Jheng KE, Taoyuan City (TW); Da Wei HUANG, Taoyuan (TW)

(21) Appl. No.: 19/135,107

(22) PCT Filed: Dec. 21, 2023
(86) PCT No.: PCT/EP23/87292

§ 371 Date: Jun. 3, 2025

(30) Foreign Application Priority Data
Dec. 29, 2022 (EP) 22217089.6

(51) Int. Cl. H10P 14/61; C09D 7/20; C09D 7/63; H10P 14/60; H10P 14/692; H10P 14/694

(52) U.S. Cl. CPC H10P 14/61; C09D 7/20; C09D 7/63; H10P 14/6339; H10P 14/69391; H10P 14/69392; H10P 14/69393; H10P 14/69474

(57) ABSTRACT

Described are a coating composition for covering a surface area on a semiconductor device during an atomic layer deposition process, a method of using the coating composition for covering a surface area on a semiconductor device during an atomic layer deposition process, and a process for the manufacture of a semiconductor device including the step of atomic layer deposition on a selected surface area.

Described are a coating composition for covering a surface area on a semiconductor device during an atomic layer deposition process, the use of said coating composition for covering a surface area on a semiconductor device during an atomic layer deposition process, and a process for the manufacture of a semiconductor device, comprising the step of atomic layer deposition on a selected surface area.

Manufacturing of advanced semiconductor devices (also referred to as “nanoelectronics”) often comprises area-selective atomic layer deposition (AS-ALD). Atomic Layer Deposition (ALD) is known in the art. It is a thin-film deposition technique by means of which a film is grown on a surface area of an object by exposing said surface area to a gas flow comprising a gaseous precursor of an atom species to be deposited on said surface area. For instance, in order to form a metal oxide layer on a surface area, a cycle (a so-called ALD cycle) is carried out comprising the steps of exposing the surface area to an oxygen-carrying precursor (e.g. water) which is chemisorbed at the surface area, removing excess molecules of the oxygen-carrying precursor by flushing with an inert gas, exposing the surface area to a metal carrying precursor (e.g. an organometallic compound) which reacts with the chemisorbed oxygen-carrying precursor to form the metal oxide, and removing excess molecules of the metal-carrying precursor and gaseous by-products by flushing with an inert gas. Further ALD cycles with the same or other precursors may follow, depending on the desired thickness and composition of the film to be formed.

In order to restrict atomic layer deposition to the desired surface area, a coating may be applied to those surface areas where no atomic layer deposition shall take place. The application of organic film coatings formed by wet treatment to those surface areas where no atomic layer deposition shall take place appears to be a promising approach for restricting the atomic layer deposition to the desired surface area. A fundamental requirement to such organic film is reliable adherence to the selected surface area without degradation during the atomic layer deposition step, even if atomic layer deposition is carried out at a rather high temperature (e.g. up to 200 °C).

Chem. Mater. 2019, 31, 1635-1645 discloses that a coating composition comprising octadecylphosphonic acid (ODPA) and t-butanol is applied to a surface area consisting of tungsten during area-selective atomic layer deposition of ZnO and Al₂O₃, resp. Herein, the highest process temperature applied for atomic layer deposition is only 120 °C.

US 2022/356566 A1 discloses a surface treatment method for a substrate surface including two or more regions, the method including reacting a compound (P-1) having the formula R¹—P(═O)(OR²)(OR³), a basic nitrogen-containing compound, and the regions with each other such that a water contact angle on the metal region is greater by 10° or more with respect to a water contact angle on an insulator region close to the metal region. In compound (P-1), R¹ is an alkyl group, an alkoxy group, a fluorinated alkyl group or an optionally substituted aromatic hydrocarbon group, and R² and R³ are each independently a hydrogen atom, an alkyl group, a fluorinated alkyl group or an optionally substituted aromatic hydrocarbon group.

US 2014/041686 A1 discloses a ready to use, aqueous cleaning, sanitizing and disinfecting composition for removing oily soils on a food contact surface.

Thus, there is an ongoing need for coating compositions for covering a surface area on a semi-conductor device during an atomic layer deposition process, with reliable adherence to the selected surface area and stability during the atomic layer deposition step, even if atomic layer deposition is carried out at a temperature of up to 200 °C. In addition, the coating composition shall be readily applicable, without foaming and any other obstacles. Moreover, the coating composition must be compatible with the material of the surface area to be coated, and must not cause corrosion of said material. More specifically, there is an ongoing need for coating compositions which are capable of forming a coating which reliably adheres to a surface area comprising or consisting of tungsten and does not degrade during the atomic layer deposition step, even if atomic layer deposition is carried out at a temperature of 200 °C or more.

These and other objects are achieved by the coating composition disclosed herein. Said coating composition for covering a surface area on a semiconductor device during an atomic layer deposition comprises:
(A) one or more compounds selected from the group consisting of compounds comprising a quaternary ammonium cation wherein at least one of the hydrocarbyl groups bond to the nitrogen atom has three or more carbon atoms compounds comprising a quaternary phosphonium cation wherein at least one of the hydrocarbyl groups bond to the phosphorus atom has three or more carbon atoms and compounds comprising an N-alkyl-pyridinium cation
(B) a buffer for adjusting a pH in the range of from 1 to 10
(C) one or more water-miscible organic solvents
(D) water.

Constituent (A) of the above-defined coating composition consists of one or more compounds which act as surfactants and are selected from the group consisting of
compounds comprising a quaternary ammonium cation wherein at least one of the hydrocarbyl groups bond to the nitrogen atom has three or more carbon atoms
compounds comprising a quaternary phosphonium cation wherein at least one of the hydrocarbyl groups bond to the phosphorus atom has three or more carbon atoms
and compounds comprising an N-alkyl-pyridinium cation.

Constituent (B) of the above-defined coating composition consists of one or more compounds which act as buffer. Said compounds of constituent (B) are not selected from the group consisting of
compounds comprising a quaternary ammonium cation wherein at least one of the hydrocarbyl groups bond to the nitrogen atom has three or more carbon atoms
compounds comprising a quaternary phosphonium cation wherein at least one of the hydrocarbyl groups bond to the phosphorus atom has three or more carbon atoms
and compounds comprising an N-alkyl-pyridinium cation.

Constituent (C) of the above-defined coating composition consists of one or more organic solvents which are miscible with water at least in a 1:1 weight ratio at 20 °C and ambient pressure. By means of appropriate selection of the solvents of constituent (C), foaming of the coating composition is avoided, and the coating composition is readily applicable to the desired surface are.

In certain cases, said coating composition consists of constituents (A), (B), (C) and (D) as defined above.

Surprisingly it has been found that a coating composition comprising or consisting of constituents (A), (B), (C) and (D) as defined above fulfils the above-defined objects. Without wishing to be bound by any theory, it is presently assumed that the surfactant(s) of constituent (A) are capable of specifically binding to a surface area comprising or consisting of tungsten, and are thermally stable at least up to 200 °C.

Preferably, in the composition according to the invention the concentration of octadecylphosphonic acid is less than 0.001%, preferably 0.0005% or less, more preferably 0.0001% or less, based on the total weight of the composition. Still more preferably, the composition according to the invention does not contain octadecylphosphonic acid.

Further preferably, in the composition according to the invention the concentration of compounds of formula

R¹—P(═O)(OR²)(OR³),

wherein R¹ is an alkyl group, an alkoxy group, a fluorinated alkyl group or an optionally substituted aromatic hydrocarbon group, and R² and R³ are each independently a hydrogen atom, an alkyl group, a fluorinated alkyl group or an optionally substituted aromatic hydrocarbon group, is less than 0.001%, preferably 0.0005% or less, more preferably 0.0001% or less, based on the total weight of the composition.

Still more preferably, the composition according to the invention does not contain any compound of formula

R¹—P(═O)(OR²)(OR³),

wherein R¹ is an alkyl group, an alkoxy group, a fluorinated alkyl group or an optionally substituted aromatic hydrocarbon group, and R² and R³ are each independently a hydrogen atom, an alkyl group, a fluorinated alkyl group or an optionally substituted aromatic hydrocarbon group.

Preferably the composition according to the invention does not contain any further surfactants beyond those of component (A).

Further preferably, in the composition according to the invention the concentration of octadecylphosphonic acid is less than 0.001%, preferably 0.0005% or less, more preferably 0.0001% or less, based on the total weight of the composition, and the composition does not contain any further surfactants beyond those of component (A).

Still further preferably, the composition according to the invention does not contain octadecylphosphonic acid and not any further surfactants beyond those of component (A).

Still further preferably, in the composition according to the invention the concentration of compounds of formula

R¹—P(═O)(OR²)(OR³),

wherein R¹ is an alkyl group, an alkoxy group, a fluorinated alkyl group or an optionally substituted aromatic hydrocarbon group, and R² and R³ are each independently a hydrogen atom, an alkyl group, a fluorinated alkyl group or an optionally substituted aromatic hydrocarbon group, is less than 0.001%, preferably 0.0005% or less, more preferably 0.0001% or less, based on the total weight of the composition, and the composition does not contain any further surfactants beyond those of component (A).

Most preferably, the composition according to the invention does not contain any compound of formula

R¹—P(═O)(OR²)(OR³),

wherein R¹ is an alkyl group, an alkoxy group, a fluorinated alkyl group or an optionally substituted aromatic hydrocarbon group, and R² and R³ are each independently a hydrogen atom, an alkyl group, a fluorinated alkyl group or an optionally substituted aromatic hydrocarbon group, and not any further surfactants beyond those of component (A).

In certain cases, a coating composition as defined above further comprises
(E) one or more oxidizing agents.

Thus, a coating composition may consist of constituents (A), (B), (C), (D) and (E) as defined above.

A coating composition as defined above is a homogeneous (i.e. single-phase) liquid under standard conditions (298 K and 101.325 kPa), wherein the constituents (A), (B) and (E) are dissolved in said liquid.

Preferably, in the coating composition as defined above the total concentration of compounds comprising a fluorine-containing anion is 0.005 wt % or less, preferably 0.001 wt % or less, more preferably 0.0001 wt % or less, based on the total mass of the coating composition. More preferably, a coating composition as described herein is free of fluorine-containing anions. Most preferably, the concentration of fluorine-comprising constituents is so low that the element fluorine is not analytically detectable in the coating composition.

In a coating composition as described herein, preferably the total amount of constituent (A) is in the range of from 0.0001 wt % to 0.05 wt % based on the sum of the masses of constituents (A), (B), (C), (D) and (E).

In a coating composition as described herein, preferably the total amount of constituent (B) is in the range of from 0.001 wt % to 1 wt % based on the sum of the masses of constituents (A), (B), (C), (D) and (E).

In a coating composition as described herein, preferably the total amount of constituent (C) is in the range of from 1 wt % to 75 wt % based on the sum of the masses of constituents (A), (B), (C), (D) and (E).

In a coating composition as described herein, preferably the total amount of constituent (E) is in the range of from 0 wt % to 1 wt % based on the sum of the masses of constituents (A), (B), (C), (D) and (E).

Most preferably, in a coating composition as defined above,
the total amount of constituent (A) is in the range of from 0.0001 wt % to 0.05 wt %
   and
the total amount of constituent (B) is in the range of from 0.001 wt % to 1 wt %
   and
the total amount of constituent (C) is in the range of from 1 wt % to 75 wt %
   and
the total amount of constituent (E) is in the range of from 0 wt % to 1 wt % in each case based on the sum of the masses of constituents (A), (B), (C), (D) and (E).
   in certain cases, the one or more compounds of constituent (A), which act as surfactants, are preferably selected from the group consisting of
compounds comprising an N-alkyl pyridinium cation wherein the alkyl has 1 to 18 carbon atoms
compounds comprising a quaternary ammonium cation [NR¹ₓR²_{y}R³_{z}]⁺, wherein
x is 2 or 3
y is 1 or 2
z is 0 or 1
x+y+z=4
R¹ is methyl or ethyl
R² and—if present—R³ are independently selected from the group consisting of alkyl having 3 to 24 carbon atoms wherein said alkyl may have one or more substituents selected from the group consisting of halogen atoms, hydroxy, benzyl and diisobutylphenoxyethoxyethyl.

The anions of said compounds comprising an N-alkyl pyridinium cation resp. a quaternary ammonium cation as defined above are preferably selected from the group consisting of chloride, bromide, and hydroxide.

In certain cases, constituent A preferably does not comprise compounds having a quaternary ammonium cation [NR¹ₓR²_{y}R³_{z}]⁺ as defined above, wherein any of R² and—if present—R³ is an alkyl having 3 to 24 carbon atoms wherein said alkyl has one or more substituents selected from the group consisting of halogen atoms.

In preferred cases, constituent A consists of compounds having a quaternary ammonium cation [NR¹ₓR²_{y}R³_{z}]⁺ as defined above, wherein any of R² and—if present—R³ is an alkyl having 3 to 24 carbon atoms, preferably 6 to 24 carbon atoms.

Preferably, all compounds of constituent (A) are selected from the above-defined group.

In certain preferred cases, the one or more compounds of constituent (A) comprise or consist of
one or more cations selected from the group consisting of (3-chloro-2-hydroxypropyl)trimethylammonium, cetrimonium (hexadecyltrimethylammonium), dodecyltrimethylammonium, hexadecyltrimethylammonium, octadecyltrimethylammonium, benzethonium, cetylpyridinium, benzyldimethylhexadecylammonium, didodecyldimethylammonium, trihexyl-tetradecyl-phosphonium, tributyl-tetradecyl-phosphonium, docosyltrimethylammonium, lauroyloxyethyltrimethylammonium, benzyldimethylstearylammonium, tributyl-hexadecylphosphonium and trimethyl-hexadecylphosphonium
and one or more anions selected from the group consisting of chloride, bromide, and hydroxide.

Preferably, all compounds of constituent (A) consist of a cation as defined above and an anion as defined above.

In certain cases, constituent A preferably does not comprise (3-chloro-2-hydroxypropyl)trimethylammonium.

Most preferably, constituent (A) comprises or consists of one or more compounds selected from the group consisting of benzyldimethylhexadecylammonium chloride, octadecyltrimethylammonium chloride (cetrimonium chloride), benzethonium chloride, cetylpyridinium chloride, docosyltrimethylammonium chloride and hexadecyltrimethylammonium chloride.

Constituent (B) comprises one or more acids and/or one or more bases which either alone or in combination act as buffers. The acids are preferably organic acids. The bases are preferably ammonium hydroxide or hydroxides having a quaternary ammonium cation wherein the hydrocarbyl groups bond to the nitrogen atom have less than three carbon atoms.

Constituent (B), which acts as buffer, preferably comprises or consists of one or more compounds selected from the group consisting of carboxylic acids (e.g. acetic acid, propionic acid), dicarboxylic acids (e.g. malic acid, succinic acid), tricarboylic acids (e.g. citric acid, trimesic acid), amino acids (e.g. glycine), polyaminocarboxylic acids (e.g. EDTA, CDTA), phosphoric acid, sulfonic acids (e.g. methanesulfonic acid, (4-(2-hydroxyethyl)-1-piperazineethanesulfonic acid) (HEPES), 2-(Cyclohexylamino)ethanesulfonic acid (CHES)), tris(hydroxymethyl)aminomethane (TRIS), ammonium hydroxide, tetramethylammonium hydroxide and tetraethylammonium hydroxide.

Preferably, all compounds of constituent (B) are selected from the above-defined group.

Most preferably, constituent (B) comprises or consists of one or both compounds selected from the group consisting of succinic acid and tetraethylammonium hydroxide.

The one or more organic water-miscible solvents of constituent (C) are preferably selected from the group consisting of glyco-ethers (e.g. butyldiglycol), alcohols (e.g. iso-propanol), sulfones (e.g. sulfolane), sulfoxides (e.g. dimethylsulfoxide DMSO), pyrrolidones (e.g. N-methyl-2-pyrrolidone, N-hydroxy-ethyl-2-pyrrolidone), morpholines (e.g. N-formylmorpholine), amine-oxides (e.g. N-methylmorpholine-N-oxide), alkanolamines (e.g. ethanolamine), dimethyl formamide, dimethyl acetamide, propylene carbonate, tetrahydrofuran, N,N′-dimethylpropylene urea, 1,3-dimethyl-2-imidazolidinone and mixtures thereof.

Preferably, all solvents of constituent (C) are selected from the above-defined group.

Most preferably, constituent (C) comprises or consists of one or more solvents selected from the group consisting of N-formylmorpholine, butyldiglycol, isopropanol, dimethylsulfoxide and sulfolane.

Preferably, all solvents of constituent (C) are selected from the above-defined preferred group.

The one or more oxidizing agents of constituent (E) are preferably selected from the group consisting of hydrogen peroxide, persulfuric acid, peracetic acid, ozone, nitric acid, periodic acid, iodic acid, perchloric acid and chloric acid. In case ozone is used as the oxidizing agent, it is dissolved in water.

Preferably, all oxidizing agents of constituent (E) are selected from the above-defined group.

Preferably, constituent (E) consists of one oxidizing agent.

Most preferably, constituent (E)—if present—comprises or consists of hydrogen peroxide.

In preferred coating compositions,
one, more or all compounds of constituent (A) are selected from the above-disclosed preferred group, and
one, more or all compounds of constituent (B) are selected from the above-disclosed preferred group, and
one, more or all solvents of constituent (C) are selected from the above-disclosed preferred group, and
one, more or all compounds of constituent (E) (if present) are selected from the above-disclosed preferred group.

Preferably, a coating composition as described herein has a pH value in the range of from 2 to 5, more preferably in the range of from 3 to 5, as measured by means of a PH meter at 25 °C, 101.325 kPa. Adjustment of the pH is achieved by means of the one or more compounds of constituent (B), which act as buffers.

Especially preferred is a coating composition, comprising or consisting of
(A) one or more compounds selected from the group consisting of benzyldimethylhexadecylammonium chloride, octadecyltrimethylammonium chloride, benzethonium chloride, cetylpyridinium chloride, docosyltrimethylammonium chloride and hexadecyltrimethylammonium chloride, wherein the total amount of said compounds is in the range of from 0.002% to 0.015%, preferably hexadecyltrimethylammonium chloride in an amount of from 0.002% to 0.015%,
and
(B) succinic acid in an amount of from 0.1% to 0.2%, and tetraethylammonium hydroxide in an amount of from 0.001% to 0.005%
and
(C) one or more solvents selected from the group consisting of N-formylmorpholine, butyldiglycol, isopropanol, dimethylsulfoxide and sulfolane, wherein the total amount of said solvents in in the range of from 10% to 50%, preferably N-formylmorpholine or sulfolane in an amount of from 10% to 50%
and
(D) water
and
(E) hydrogen peroxide in an amount of from 0% to 1%
in each case based on the sum of the masses of above-defined constituents (A), (B), (C), (D) and (E),
wherein the coating composition has a pH value in the range of from 3 to 5 as measured by means of a pH meter at 25 °C, 101.325 kPa.

Most preferred is a coating composition comprising or consisting of
(A) hexadecyltrimethylammonium chloride in an amount of from 0.002% to 0.015%,
and
(B) succinic acid in an amount of from 0.1% to 0.2%, and tetraethylammonium hydroxide in an amount of from 0.001% to 0.005%
and
(C) N-formylmorpholine or sulfolane in an amount of from 10% to 50% and
(D) water
in each case based on the sum of the masses of above-defined constituents (A), (B), (C), and (D)
wherein the coating composition has a pH value in the range of from 4 to 5 as measured by means of a pH meter at 25 °C, 101.325 kPa.

According to a further aspect, the present disclosure relates to the use of a coating composition as defined above for covering a surface area on a semiconductor device during an atomic layer deposition process. Thus, the coating composition as defined above is used for achieving an area-selective atomic layer deposition leaving out the covered surface area.

Regarding specific and preferred coating compositions for the above-defined use, reference is made to the disclosure provided above in the context of the description of the coating composition.

Preferred is a use of a coating composition as defined above for covering a surface area comprising or consisting of tungsten on a semiconductor device during an atomic layer deposition process. Thus, the coating composition as defined above is used for achieving an area-selective atomic layer deposition leaving out the covered surface area comprising or consisting of tungsten.

In the use as above-defined, the surface area selected for atomic layer deposition may comprise or consist of a material selected from the group consisting of
a bottom anti-reflective coating (an essential material used in lithographic processes)
a material having a dielectric constant k<3.9 (so-called low k material), e.g. SiO₂, silicon oxycarbide (SiOC), tetraethylorthosilicate (TEOS), boron-doped phosphosilicate glass (BPSG), fluorine-doped silicon dioxide (fluorosilicateglass, FSG), carbon-doped silicon dioxide, organo silicate glass (OSG), carbon-doped silicon oxide (CDO), porous silicon dioxide, porous carbon-doped silicon-dioxide
a compound of aluminum, e.g. aluminum oxide (AlOx), aluminum nitride (AlNx), aluminum oxynitride (AlON), aluminum carbooxynitride (AlOCN), aluminum carbooxynitride fluoride (AlOCNF),
a compound of titanium, e.g. TiN.

Usually, the surface area selected for atomic layer deposition consists of one of the abovementioned materials.

In the use as defined above, area-selective atomic layer deposition may be carried out to form a layer comprising or consisting of one or more of aluminium oxide, tantalum oxide, tantalum nitride and hafnium oxide on a surface area selected for atomic layer deposition, i.e. on a surface area of the semiconductor device not covered by a coating formed from the above-defined coating composition. Usually the layer formed by area-selective atomic layer deposition consists of one or more of aluminium oxide, tantalum oxide, tantalum nitride and hafnium oxide.

Typically, the layer formed by area-selective atomic layer deposition has a thickness in the range of from 1 nm to 10 nm.

Atomic layer deposition is known as such and may be carried out in any suitable manner using any suitable equipment. Preferably, atomic layer deposition is carried out at a temperature in the range of from 50 °C to 350 °C, more preferably at a temperature in the range of from 120 °C to 300 °C, further preferably at a temperature in the range of from 150 °C to 250 °C and most preferably at a temperature in the range of from 150 °C to 220 °C.

According to a further aspect, the present disclosure relates to a process for the manufacture of a semiconductor device. Said process comprises atomic layer deposition on a selected surface area, wherein atomic layer deposition comprises the steps of
applying a coating composition as defined above to a surface area of a semiconductor device where no atomic layer deposition shall take place
subjecting the semiconductor device to area-selective atomic layer deposition.

Regarding specific and preferred coating compositions for the above-defined process, reference is made to the disclosure provided above in the context of the description of the coating composition.

In the above-defined process, applying a coating composition as defined above to a surface area of a semiconductor device where no atomic layer deposition shall take place may be carried out in any suitable manner using any suitable means. For instance, the coating composition may be applied by means of dipping (immersing the surface area of a semiconductor device which is to be coated into the coating composition), rinsing, and spraying.

In the above-defined process, the surface area of a semiconductor device where no atomic layer deposition shall take place preferably comprises of consists of tungsten. Thus, in the above-defined process the coating composition as defined above is preferably applied to a surface area comprising or consisting of tungsten.

In the above-defined process, the surface area selected for atomic layer deposition may comprise or consist of a material selected from the group consisting of
a bottom anti-reflective coating (an essential material used in lithographic processes)
a material having a dielectric constant k<3.9 (so-called low k material), e.g. SiO₂, silicon oxycarbide (SiOC), tetraethylorthosilicate (TEOS), boron-doped phosphosilicate glass (BPSG), fluorine-doped silicon dioxide (fluorosilicateglass, FSG), carbon-doped silicon dioxide, organo silicate glass (OSG), carbon-doped silicon oxide (CDO), porous silicon dioxide, porous carbon-doped silicon-dioxide
a compound of aluminum, e.g. aluminum oxide (AlOx), aluminum nitride (AlNx), aluminum oxynitride (AlON), aluminum carbooxynitride (AlOCN), aluminum carbooxynitride fluoride (AlOCNF),
a compound of titanium, e.g. TiN.

In the above-defined process, area-selective atomic layer deposition may be carried out to form a layer comprising or consisting of one or more of aluminium oxide, tantalum oxide, tantalum nitride and hafnium oxide on a surface area selected for atomic layer deposition i.e. on a surface area of the semiconductor device not coated by the above-defined coating composition. Usually the layer formed by area-selective atomic layer deposition consists of one or more of aluminium oxide, tantalum oxide, tantalum nitride and hafnium oxide.

Preferably, atomic layer deposition is carried out at a temperature in the range of from 50 °C to 350 °C, more preferably at a temperature in the range of from 120 °C to 300 °C, further preferably at a temperature in the range of from 150 °C to 250 °C and most preferably at a temperature in the range of from 150 °C to 220 °C.

An especially preferred process according to the present disclosure comprises the steps of
applying a coating composition comprising or consisting of
(A) one or more compounds selected from the group consisting of benzyldimethylhexadecylammonium chloride, octadecyltrimethylammonium chloride, benzethonium chloride, cetylpyridinium chloride, docosyltrimethylammonium chloride and hexadecyltrimethylammonium chloride, wherein the total amount of said compounds is in the range of from 0.002% to 0.015%
and
(B) succinic acid in an amount of from 0.1% to 0.2%, and tetraethylammonium hydroxide in an amount of from 0.001% to 0.005%
and
(C) one or more solvents selected from the group consisting of N-formylmorpholine, butyldiglycol, isopropanol, dimethylsulfoxide and sulfolane, wherein the total amount of said solvents in a range of from 10% to 50%, preferably N-formylmorpholine or sulfolane in an amount of from 10% to 50%
and
(D) water
and
(E) hydrogen peroxide in an amount of from 0% to 1%
in each case based on the sum of the masses of above-defined constituents (A), (B), (C), (D) and (E), wherein the coating composition has a pH value in the range of from 3 to 5 s measured by means of a pH meter at 25 °C, 101.325 kPa
to a surface area of a semiconductor device where no atomic layer deposition shall take place, wherein said surface area where no atomic layer deposition shall take place comprises or consists of tungsten
subjecting the semiconductor device to atomic layer deposition of one or more of aluminium oxide, tantalum oxide, tantalum nitride and hafnium oxide on a surface area comprising of consisting of a material selected from the group consisting of
   a bottom anti-reflective coating (an essential material used in lithographic processes)
   a material having a dielectric constant k<3.9 (so-called low k material), e.g. SiO₂, silicon oxycarbide (SiOC), tetraethylorthosilicate (TEOS), boron-doped phosphosilicate glass (BPSG), fluorine-doped silicon dioxide (fluorosilicateglass, FSG), carbon-doped silicon dioxide, organo silicate glass (OSG), carbon-doped silicon oxide (CDO), porous silicon dioxide, porous carbon-doped silicon-dioxide
   a compound of aluminum, e.g. aluminum oxide (AlOx), aluminum nitride (AlNx), aluminum oxynitride (AlON), aluminum carbooxynitride (AlOCN), aluminum carbooxynitride fluoride (AlOCNF),
   a compound of titanium, e.g. TiN.
at a temperature in the range of from 150 °C to 250 °C, preferably 150 °C to 220 °C.

Most preferably, the coating composition applied in the above-defined process comprises or consists of
(A) hexadecyltrimethylammonium chloride in an amount of from 0.002% to 0.015%,
and
(B) succinic acid in an amount of from 0.1% to 0.2%, and tetraethylammonium hydroxide in an amount of from 0.001% to 0.005%
and
(C) N-formylmorpholine or sulfolane in an amount of from 10% to 50%
and
(D) water
in each case based on the sum of the masses of above-defined constituents (A), (B), (C), and (D)
wherein the coating composition has a pH value in the range of from 4 to 5.

According to a further aspect, there is disclosed a semiconductor device having a surface area comprising or consisting of tungsten, wherein said surface area is covered by a coating comprising or consisting of one or more compounds selected from the group consisting of
compounds comprising a quaternary ammonium cation wherein at least one of the hydrocarbyl groups bond to the nitrogen atom has three or more carbon atoms
compounds comprising a quaternary phosphonium cation wherein at least one of the hydrocarbyl groups bond to the phosphorus atom has three or more carbon atoms
and compounds comprising an N-alkyl-pyridinium cation.

According to a further aspect, there is disclosed the use of one or more compounds selected from the group consisting of
compounds comprising a quaternary ammonium cation wherein at least one of the hydrocarbyl groups bond to the nitrogen atom has three or more carbon atoms
compounds comprising a quaternary phosphonium cation wherein at least one of the hydrocarbyl groups bond to the phosphorus atom has three or more carbon atoms
and compounds comprising an N-alkyl-pyridinium cation
   for forming a coating on a surface area of a semiconductor device wherein said surface area comprises or consists of tungsten.

### EXAMPLES

The following examples are meant to further explain the invention without limiting its scope.

In tables 1~4 (see below), CAS No refers to the number of the related compounds in the Chemical Abstracts.

### 1. Screening of Surfactants by Evaluation of the Etching Rate of Tungsten

Each composition according to table 1 was applied to a coupon made of tungsten (2 cm*2 cm area deposited by CVD on a silicon wafer), and the etching rate for tungsten was determined at 40 °C under mechanical stirring.

For determining the initial layer thickness of tungsten, an X-ray diffraction fluorescence (XRF)-recipe was created for the pristine coupons, based on the thickness of the CVD-deposited tungsten layer verified with transmission electron microscopy (TEM) of the cross-section of said layer. Each coupon was fixed to a mechanical holder and was contacted with a composition of table 1 (which was in a beaker) for a reaction time of 10 minutes. Subsequently, the coupons were withdrawn from the compositions and rinsed for 10 seconds with ultra-pure water followed by 10 seconds of isopropyl alcohol. Afterwards, the coupons were dried with nitrogen gas. The residual thickness of the tungsten layers after exposure to the composition was measured again as described above and the etch loss was calculated by subtracting the layer thickness after contact with the composition from the thickness of the same layer before exposure to the composition.

In the compositions of table 1, succinic acid and tetraethylammonium hydroxide act as buffer (B), and N-formylmorpholine is the solvent (C). Composition #1 does not contain constituent (A) as defined above. Compositions #2 to #7 contain a constituent (A) as indicated in table 1.

Compositions #4, #5, #6 and #7 are most effective in inhibiting the corrosion of tungsten. Thus, the surfactants hexadecyltrimethyl ammonium chloride, octadecyltrimethylammonium chloride, benzethonium chloride and cetylpyridinium chloride are very promising candidates for constituent (A) of a coating composition as defined above. Composition #3 comprising the surfactant dodecyltrimethyl ammonium chloride moderately inhibits the corrosion of tungsten. In contrast composition #2 comprising (3-chloro-2-hydroxypropyl)trimethylammonium chloride is less efficient in inhibiting the corrosion of tungsten. Therefore (3-chloro-2-hydroxypropyl)trimethylammonium is a less preferred candidate for constituent (A).

TABLE 1

| | | composition # | | | | | | |
|---|---|---|---|---|---|---|---|---|
| | | 1 | 2 | 3 | 4 | 5 | 6 | 7 |
| CAS No. | constituents | wt % | wt % | wt % | wt % | wt % | wt % | wt % |
| 110-15-6 | succinic acid | 0.1 | 0.1 | 0.1 | 0.1 | 0.1 | 0.1 | 0.1 |
| 77-98-5 | tetraethylammonium | 0.01 | 0.01 | 0.01 | 0.01 | 0.01 | 0.01 | 0.01 |
| | hydroxide | | | | | | | |
| 4394-85-8 | N-formylmorpholine | 25 | 25 | 25 | 25 | 25 | 25 | 25 |
| 3327-22-8 | (3-chloro-2-hydroxypropyl) | — | 0.1 | — | — | — | — | — |
| | trimethylammonium chloride | | | | | | | |
| 112-00-5 | Dodecyltrimethyl | — | — | 0.01 | — | — | — | — |
| | ammonium chloride (C12) | | | | | | | |
| 112-02-7 | Hexadecyltrimethyl | — | — | — | 0.01 | — | — | — |
| | ammonium chloride (C16) | | | | | | | |
| 112-03-8 | Octadecyltrimethylammonium | — | — | — | — | 0.002 | — | — |
| | chloride (C18) | | | | | | | |
| 121-54-0 | Benzethonium chloride | — | — | — | — | — | 0.1 | — |
| 123-03-5 | Cetylpyridinium chloride | — | — | — | — | — | — | 0.01 |
| | water | balance in each case | | | | | | |
| | pH value | 4.5 | 4.5 | 4.5 | 4.5 | 4.5 | 4.5 | 4.5 |
| | E/R(Å/min) on W 400 nm | 1.4 | 1.3 | 1.1 | 0.5 | 0.3 | 0.02 | 0.3 |
| | thick film @ 40 °C, 10 min | | | | | | | |

### 2. Screening of Organic Solvents for Defoaming Efficiency

10 ml of each composition of table 2 were shaken for 30 seconds to generate maximum foam. Thereafter, the foam height was measured (H₀), the compositions were allowed to idle for 10 seconds and then the foam height was measured again (H₁₀).

In the compositions of table 2, succinic acid and tetraethylammonium hydroxide act as buffer (B), and hexadecyltrimethylammonium chloride is the constituent (A). Composition #12 does not contain constituent (C) as defined above. Compositions #4 and #8 to #11 contain an organic solvent (C) as indicated in table 2.

All tested organic solvents were efficient in defoaming, compared to the comparison composition #12 which does not contain any organic solvent.

TABLE 2

| | | composition # | | | | | |
|---|---|---|---|---|---|---|---|
| | | 4 | 8 | 9 | 10 | 11 | 12 |
| CAS No | constituents | wt % | wt % | wt % | wt % | wt % | wt % |
| 110-15-6 | succinic acid | 0.1 | 0.1 | 0.1 | 0.1 | 0.1 | 0.05 |
| 77-98-5 | tetraethylammonium hydroxide | 0.01 | 0.01 | 0.01 | 0.01 | 0.01 | 0.01 |
| 4394-85-8 | N-formylmorpholine | 25 | — | — | — | — | — |
| 112-34-5 | butyldiglycol | — | 25 | — | — | — | — |
| 67-63-0 | isopropanol | — | — | 25 | — | — | — |
| 67-68-5 | dimethylsulfoxide | — | — | — | 25 | — | — |
| 126-33-0 | sulfolane | — | — | — | — | 25 | — |
| 112-02-7 | hexadecyltrimethylammonium chloride | 0.01 | 0.01 | 0.01 | 0.01 | 0.01 | 0.01 |
| | water | Balance in each case | | | | | |
| | pH value | 4.5 | 4.5 | 4.5 | 4.5 | 4.5 | 4.5 |
| | H₀ (cm) | 1 | 0.5 | 1 | 1.3 | 1.5 | 4 |
| | H₁₀ (cm) | 0.4 | 0.2 | 0.5 | 0.5 | 0.7 | 4 |

### 3. XPS Analysis of Tungsten Surfaces to Check Adherence of the Surfactant (A)

Into each coating composition of table 3 a coupon made of tungsten (2 cm*2 cm area deposited by CVD on a silicon wafer) was dipped for one minute at a temperature of 40 °C. Then, each coupon was rinsed with de-ionized water followed by isopropyl alcohol and subjected to analysis by means of XPS (X-ray Photoelectron Spectroscopy) for determining the concentration of carbon at the surface area (2 cm*2 cm). For comparison, the carbon concentration on the surface area (2 cm*2 cm) of a coupon not dipped in any coating composition was determined (cf. column “non-treated coupon” in table 3).

A high carbon concentration on the surface area analyzed by XPS is an indicator for formation of a coating comprising surfactant (A) of the coating composition.

In the coating compositions of table 3, succinic acid and tetraethylammonium hydroxide act as buffer (B), and hydrogen peroxide (if present) acts as oxidizing agent (E). The organic solvent (C) is one of N-formylmorpholine, dimethylsulfoxide, butyldiglycol, isopropanol and sulfolane, as indicated in table 3. Constituent (A) is one of hexadecyltrimethylammonium chloride, benzethonium chloride, cetylpyridinium chloride and docosyltrimethylammonium chloride, as indicated in table 3.

With each coating composition of table 3, a significant increase of the carbon concentration on the surface area analyzed by XPS was found, compared to the coupon not dipped in any coating composition. Thus, the surfactants (A) used in the coating compositions of table 3 readily adhere to the surface area consisting of tungsten.

Table 3 also shows that for a specific surfactant (A), the selection of the organic solvent (C) and its amount may have an influence on the amount of adsorbed surfactant, cf. coating compositions #4, 13, 8, 9, 11 and 14 (each having hexadecyltrimethylammonium chloride as constituent (A)); and for a specific organic solvent (C), the selection of surfactant (A) may have an influence on the amount of adsorbed surfactant, cf. coating compositions #4, 6 and 15 (each having N-formylmorpholine as the solvent). Thus, by proper selection of the surfactant (A) and the organic solvent (C), the amount of adhering surfactant may be optimized.

TABLE 3

| | | | composition # | | | | | | | | | | |
|---|---|---|---|---|---|---|---|---|---|---|---|---|---|
| | | | 4 | 13 | 8 | 9 | 11 | 14 | 6 | 15 | 17 | 18 | 19 |
| CAS No. | constituents | | wt % | wt % | wt % | wt % | wt % | wt % | wt % | wt % | wt % | wt % | wt % |
| 110-15-6 | succinic acid | non- | 0.1 | 0.2 | 0.1 | 0.1 | 0.1 | 0.2 | 0.1 | 0.1 | 0.3 | 0.2 | 0.2 |
| 77-98-5 | tetraethylammonium hydroxide | treated | 0.01 | 0.01 | 0.01 | 0.01 | 0.01 | 0.01 | 0.01 | 0.01 | 0.01 | 0.01 | 0.01 |
| 4394-85-8 | N-formylmorpholine | coupon | 25 | 35 | — | — | — | — | 25 | 25 | — | — | — |
| 67-68-5 | dimethylsulfoxide | | — | — | — | — | — | — | — | — | 70 | | — |
| 112-34-5 | butyldiglycol | | — | — | 25 | — | — | — | — | — | — | | — |
| 67-63-0 | isopropanol | | — | — | — | 25 | — | — | — | — | — | | — |
| | sulfolane | | — | — | — | — | 25 | 40 | — | — | — | 40 | 40 |
| 112-02-7 | hexadecyltrimethylammonium chloride | | 0.01 | 0.01 | 0.01 | 0.01 | 0.01 | 0.01 | — | — | — | — | — |
| 112-03-8 | octadecyltrimethylammonium chloride | | | | | | | | | | | 0.01 | 0.01 |
| 121-54-0 | benzethonium chloride | | — | — | — | — | — | — | 0.1 | — | — | | |
| 123-03-5 | cetylpyridinium chloride | | — | — | — | — | — | — | — | 0.01 | — | — | — |
| 17301-53-0 | docosyltrimethylammonium chloride | | — | — | — | — | — | — | — | — | 0.005 | — | — |
| 7722-84-1 | hydrogen peroxide | | — | — | — | — | — | — | — | — | — | — | 0.001 |
| | water | | Balance in each case | | | | | | | | | | |
| | pH value | | 4.5 | 4.5 | 4.5 | 4.5 | 4.5 | 4.5 | 4.5 | 4.5 | 5 | 4.5 | 4.5 |
| | at % of Carbon on W coupon | 13% | 43% | 38% | 35% | 42% | 48% | 44% | 47% | 53% | 61% | 44% | 45% |

### 4. Test of Stability of Surfactant (A) During Atomic Layer Deposition of TaO at 200 °C.

Into each coating composition of table 4 a coupon made of tungsten (2 cm*2 cm area deposited by CVD on a silicon wafer) was dipped for one minute at a temperature of 40 °C. Then, each coupon was rinsed with de-ionized water followed by isopropyl alcohol and subjected to atomic layer deposition of TaO (68 cycles at 200 °C, allowing for deposition of a 0.15 nm thick layer of TaO per cycle) at the surface area (2 cm*2 cm). For comparison, a coupon not dipped in any coating composition was subjected to atomic layer deposition of TaO (68 cycles at 200 °C, allowing for deposition of a 0.15 nm thick layer of TaO per cycle) at the surface area (2 cm*2 cm) (cf. column “non-treated coupon” in table 4). The concentration of tantalum (Ta) on the surface area subjected to atomic layer deposition was determined by means of XPS analysis.

A low concentration of tantalum at the surface area analyzed by XPS is an indicator for stability of the surfactant (A) of the coated surface area during the atomic layer deposition step carried out at 200 °C, so that atomic layer deposition of TaO is effectively reduced.

With each coating composition of table 4, a significant decrease of the tantalum concentration on the surface area analyzed by XPS was found, compared to the coupon not dipped in any coating composition. Thus, the surfactants (A) used in the coating compositions of table 4 have sufficient thermal stability during atomic layer deposition of TaO at 200 °C, so that atomic layer deposition is effectively reduced.

Table 4 also shows that for a specific surfactant (A), the selection of the organic solvent (C) and its amount may have an influence on the efficiency of preventing atomic layer deposition, cf. coating compositions #4, 13, 8, 9, 11 and 14 (each having hexadecyltrimethylammonium chloride as constituent (A)); and for a specific organic solvent (C), the selection of surfactant (A) may have an influence on the efficiency of preventing atomic layer deposition, cf. coating compositions #4, 6 and 15 (each having N-formylmorpholine as the solvent). Thus, by proper selection of the surfactant (A) and the organic solvent (C), the efficiency of atomic layer deposition of TaO at 200 °C may be optimized.

TABLE 4

| | | | composition # | | | | | | | | |
|---|---|---|---|---|---|---|---|---|---|---|---|
| | | | 4 | 13 | 8 | 9 | 11 | 14 | 6 | 15 | 17 |
| CAS No. | constituents | | wt % | wt % | wt % | wt % | wt % | wt % | wt % | wt % | wt % |
| 110-15-6 | succinic acid | Non- | 0.1 | 0.2 | 0.1 | 0.1 | 0.1 | 0.2 | 0.1 | 0.1 | 0.3 |
| 77-98-5 | tetraethylammonium hydroxide | treated | 0.01 | 0.01 | 0.01 | 0.01 | 0.01 | 0.01 | 0.01 | 0.01 | 0.01 |
| 4394-85-8 | N-formylmorpholine | coupon | 25 | 35 | — | — | — | — | 25 | 25 | — |
| 67-68-5 | dimethylsulfoxide | | — | — | — | — | — | — | — | — | 70 |
| 112-34-5 | butyldiglycol | | — | — | 25 | — | — | — | — | — | — |
| 67-63-0 | isopropanol | | — | — | — | 25 | — | — | — | — | — |
| | sulfolane | | — | — | — | — | 25 | 40 | — | — | — |
| 112-02-07 | hexadecyltrimethylammonium chloride | | 0.01 | 0.01 | 0.01 | 0.01 | 0.01 | 0.01 | | | |
| 121-54-0 | benzethonium chloride | | | | | | | | 0.1 | — | — |
| 123-03-5 | cetylpyridinium chloride | | — | — | — | — | — | — | — | 0.01 | — |
| 17301-53-0 | docosyltrimethylammonium chloride | | — | — | — | — | — | — | — | — | 0.005 |
| | water | | Balance in each case | | | | | | | | |
| | pH value | | 4.5 | 4.5 | 4.5 | 4.5 | 4.5 | 4.5 | 4.5 | 4.5 | 5 |
| | at % of Tantalum on W coupon | 13.1 | 1.8 | 1.8 | 12.5 | 7.9 | 2.3 | 3.2 | 4 | 9.3 | 9.8 |

1. A method of using a coating composition, the method comprising using the coating composition for covering a surface area on a semiconductor device during an atomic layer deposition process,
said coating composition comprising
(A) one or more compounds selected from the group consisting of
compounds comprising a quaternary ammonium cation wherein at least one of the hydrocarbyl groups bonded to the nitrogen atom has three or more carbon atoms,
compounds comprising a quaternary phosphonium cation wherein at least one of the hydrocarbyl groups bonded to the phosphorus atom has three or more carbon atoms, and
compounds comprising an N-alkyl-pyridinium cation;
(B) a buffer for adjusting a pH in the range of from 1 to 10;
(C) one or more water-miscible organic solvents; and
(D) water.

2. The method according to claim 1, wherein the coating composition further comprises
(E) one or more oxidizing agents.

3. The method according to claim 1, wherein in the coating composition a total concentration of compounds comprising a fluorine-containing anion is 0.005 wt % or less based on the total mass of the coating composition.

4. The method according to claim 2, wherein in the coating composition
a total amount of constituent (A) is in a range of from 0.0001 wt % to 0.05 wt %;
and/or
a total amount of constituent (B) is in a range of from 0.001 wt % to 1 wt %;
and/or
a total amount of constituent (C) is in a range of from 1 wt % to 75 wt %;
and/or
a total amount of constituent (E) is in a range of from 0 wt % to 1 wt %,
in each case based on the sum of the masses of constituents (A), (B), (C), (D) and (E).

5. The method according to claim 1, wherein in the coating composition the one or more compounds of constituent (A) are selected from the group consisting of
compounds comprising an N-alkyl pyridinium cation wherein the alkyl has 1 to 18 carbon atoms; and
compounds comprising a quaternary ammonium cation [NR¹ₓR²_{y}R³_{z}]⁺, wherein
x is 2 or 3;
y is 1 or 2;
z is 0 or 1;
x+y+z=4;
R¹ is methyl or ethyl; and
R² and R³ are independently selected from the group consisting of alkyl having 3 to 24 carbon atoms wherein said alkyl may have one or more substituents selected from the group consisting of halogen atoms, hydroxy, benzyl and diisobutylphenoxyethoxyethyl.

6. The method according to claim 1, wherein in the coating composition the one or more compounds of constituent (A) comprise
one or more cations selected from the group consisting of (3-chloro-2-hydroxypropyl)trimethylammonium, cetrimonium, dodecyltrimethyl-ammonium, hexadecyltrimethylammonium, octadecyltrimethylammonium, benzethonium, cetylpyridinium, benzyldimethylhexadecylammonium, didodecyldimethylammonium, trihexyl-tetradecylphosphonium, tributyl-tetradecyl-phosphonium, docosyltrimethylammonium, lauroyloxyethyltrimethylammonium, benzyldimethylstearylammonium, tributyl-hexadecylphosphonium and trimethyl-hexadecylphosphonium; and
one or more anions selected from the group consisting of chloride, bromide, and hydroxide.

7. The method according to claim 1, wherein in the coating composition constituent (B) consists of one or more compounds selected from the group consisting of carboxylic acids, dicarboxylic acids, tricarboxylic acids, amino acids, polyaminocarboxylic acids, phosphoric acid, sulfonic acids, tris(hydroxymethyl)aminomethane, ammonium hydroxide, tetramethylammonium hydroxide and tetraethylammonium hydroxide.

8. The method according to claim 1, wherein in the coating composition the one or more water-miscible organic solvents of constituent (C) are selected from the group consisting of glyco-ethers, alcohols, sulfones, sulfoxides, pyrrolidones, morpholines, amine-oxides, alkanolamines, dimethyl formamide, dimethyl acetamide, propylene carbonate, tetrahydrofuran, N,N′-dimethylpropylene urea, 1,3-dimethyl-2-imidazolidinone and mixtures thereof.

9. The method according to claim 2, wherein in the coating composition the one or more oxidizing agents of constituent (E) are selected from the group consisting of hydrogen peroxide, persulfuric acid, peracetic acid, ozone, nitric acid, periodic acid, iodic acid, perchloric acid, and chloric acid.

10. The method according to claim 1, wherein said coating composition has a pH value in the range of from 2 to 5.

11. The method according to claim 1, wherein the coating composition comprises
(A) one or more compounds selected from the group consisting of benzyldimethylhexadecylammonium chloride, octadecyltrimethylammonium chloride, benzethonium chloride, cetylpyridinium chloride, docosyltrimethylammonium chloride and hexadecyltrimethylammonium chloride, wherein the total amount of said compounds is in the range of from 0.002% to 0.015%;
(B) succinic acid in an amount of from 0.1% to 0.2%, and tetraethylammonium hydroxide in an amount of from 0.001% to 0.005%;
(C) one or more solvents selected from the group consisting of N-formylmorpholine, butyldiglycol, isopropanol, dimethylsulfoxide and sulfolane, wherein the total amount of said solvents in the range of from 10% to 50%;
(D) water; and
(E) hydrogen peroxide in an amount of from 0% to 1% 2
in each case based on the sum of the masses of constituents (A), (B), (C), (D) and (E),
wherein the coating composition has a pH value in the range of from 3 to 5.

12. The method according to claim 1, the method comprising using the coating composition for covering a surface area comprising tungsten on a semiconductor device during an atomic layer deposition process.

13. A process for the manufacture of a semiconductor device, comprising atomic layer deposition on a selected surface area comprising the steps of
applying a coating composition as defined in claim 1 to a surface area of a semiconductor device where no atomic layer deposition shall take place; and
subjecting the semiconductor device to atomic layer deposition.

14. The process according to claim 13, wherein
the coating composition as defined in claim 1 is applied to a surface area comprising tungsten;
and/or
the surface area selected for atomic layer deposition comprises a material selected from the group consisting of
a bottom anti-reflective coating,
a material having a dielectric constant k<3.9,
a compound of aluminum, and
a compound of titanium.

15. The process according to claim 13, wherein
one or more of aluminium oxide, tantalum oxide, tantalum nitride and hafnium oxide are formed by atomic layer deposition on the surface area selected for atomic layer deposition;
and/or
atomic layer deposition is carried out at a temperature in the range of from 50 °C to 350 °C.

16. A coating composition for covering a surface area on a semiconductor device during an atomic layer deposition process, said composition comprising
(A) one or more compounds selected from the group consisting of benzyldimethylhexadecylammonium chloride, octadecyltrimethylammonium chloride, benzethonium chloride, cetylpyridinium chloride, docosyltrimethylammonium chloride and hexadecyltrimethylammonium chloride, wherein the total amount of said compounds is in the range of from 0.002% to 0.015%;
(B) succinic acid in an amount of from 0.1% to 0.2%, and tetraethylammonium hydroxide in an amount of from 0.001% to 0.005%;
(C) one or more solvents selected from the group consisting of N-formylmorpholine, butyldiglycol, isopropanol, dimethylsulfoxide and sulfolane, wherein the total amount of said solvents in the range of from 10% to 50%;
(D) water; and
(E) hydrogen peroxide in an amount of from 0% to 1% 2
in each case based on the sum of the masses of constituents (A), (B), (C), (D) and (E),
wherein the coating composition has a pH value in the range of from 3 to 5.

17. The method according to claim 1, wherein in the coating composition a total concentration of compounds comprising a fluorine-containing anion is 0.001 wt % or less based on the total mass of the coating composition.

18. The method according to claim 1, wherein in the coating composition a total concentration of compounds comprising a fluorine-containing anion is 0.0001 wt % or less based on the total mass of the coating composition.

19. The process according to claim 13, wherein
one or more of aluminium oxide, tantalum oxide, tantalum nitride and hafnium oxide are formed by atomic layer deposition on the surface area selected for atomic layer deposition;
and/or
atomic layer deposition is carried out at a temperature in the range of from 120 °C to 300 °C.

20. The process according to claim 13, wherein
one or more of aluminium oxide, tantalum oxide, tantalum nitride and hafnium oxide are formed by atomic layer deposition on the surface area selected for atomic layer deposition;
and/or
atomic layer deposition is carried out at a temperature in the range of from 150 to 200 °C.
